(19) United States
(12) Patent Application Publication
(10) Pub. No.: US 2013/0011945 A1
(43) Pub. Date: Jan. 10, 2013

(54) IMAGE DISPLAYING DEVICE

(75) Inventors: Isao SUZUMURA, Tokyo (JP); Yoshiaki Toyota, Hachioji (JP)

(73) Assignees: Panasonic Liquid Crystal Display Co., Ltd., Hyogo-ken (JP); Hitachi Displays, Ltd., Chiba (JP)

(21) Appl. No.: 13/618,083

(22) Filed: Sep. 14, 2012

Related U.S. Application Data
(63) Continuation of application No. 12/219,435, filed on Jul. 22, 2008.

(30) Foreign Application Priority Data
Jul. 30, 2007 (JP) JP 2007-196996

(51) Int. Cl. H01L 33/48

(52) U.S. Cl. 438/24; 257/E33.077

(57) ABSTRACT

An image displaying device having multiple photosensing devices have successfully suppressed a leakage current from each photosensing device and improved the S/N ratio. In the image displaying device, pixels and photosensing devices are disposed as pairs in a matrix pattern on a substrate. Each of the pixels and each of the photosensing devices are driven independently. Each photosensing device includes a semiconductor layer that is a photoelectric conversion layer connected to at least a first electrode and a second electrode. The contact surfaces of the first and second electrodes with respect to the semiconductor layer are disposed so that their center axes are separated from each other.

### CLAIM OF PRIORITY

This application is a Continuation application of U.S. application Ser. No. 12/219,435 filed Jul. 22, 2008. The present application claims priority from U.S. application Ser. No. 12/219,435 filed Jul. 22, 2008, which claims priority from Japanese patent application JP 2007-196996 filed on Jul. 30, 2007, the content of which is hereby incorporated by reference into this application.

### FIELD OF THE INVENTION

The present invention relates to an image displaying device, more particularly to an image displaying device having a plurality of built-in photosensing devices.

### BACKGROUND OF THE INVENTION

There is a well-known liquid crystal display device used, for example, for mobile phones or on-vehicle units/devices. The display device includes a touch panel function mechanism allowing input operations from the touch panel.

Among such touch panel function mechanisms, there is a well-known one formed by integrating its sensors and pixels at one-to-one correspondence in the liquid crystal display device.

Each sensor is configured by a photo sensor with Schottky-barrier configured so as to have a metal layer and a semiconductor layer with a junction therebetween or a pin-type photo sensor configured so as to have p-type and n-type semiconductor layers with a non-doped semiconductor layer therebetween.

A photo sensor configured in such a way comes to have a photocurrent and a dark current that differ in size from each other by several figures when it receives a reverse bias. Consequently, the photo sensor is expected to have a high S/N (signal-to-noise) ratio.

The liquid crystal display device configured in such a way is disclosed, for example, in JP-A-Hei11(1999)-125841.

### SUMMARY OF THE INVENTION

In case of the image displaying device configured as described above, however, a center axis of the interface between the first electrode and the semiconductor layer is aligned with a center axis of the interface between the second electrode and the semiconductor layer.

Consequently, a high electric field is induced mainly to a depletion layer formed in the semiconductor layer, thereby a leak current is generated and the dark current increases easily. This has prevented the improvement of the S/N ratio.

When lowering the electric field strength, increasing the film thickness of the semiconductor layer might be one of conceivable methods. However, this will result in increasing the depositing time and preventing the smoothing of the substrate surface on which the photosensors are formed. Furthermore, it will cause degradation of the display quality.

Under such circumstances, it is an object of the present invention to provide an image displaying device capable of suppressing the generation of the leakage current in each photosensing device, thereby having further successfully improved the S/N ratio.

Hereunder, there will be described briefly the features of the typical objects of the present invention disclosed in this specification.

(1) According to the first aspect of the present invention, the image displaying device includes a plurality of pixels and a plurality of photosensing devices combined on a substrate in a matrix pattern. Each of the pixels and each of the photosensing devices are driven independently of others.

Each of the photosensing devices includes a semiconductor layer consisting of a photoelectric conversion layer connected at least to a first electrode and a second electrode. A center axis of the interface between the first electrode and the semiconductor layer is separated from a center axis of the interface between the second electrode and the semiconductor layer.

(2) According to the second aspect of the present invention, the image displaying device is premised to have, for example, the configuration in (1) and each photosensing device has a switching element. The switching element is turned on/off to take out the current generated in the semiconductor layer.

(3) According to the third aspect of the present invention, the image displaying device is premised to have, for example, the configuration in (2) and the semiconductor layer is connected to the first electrode by contact at its one end and to the second electrode at the other end. The first electrode also functions as one electrode of the switching element.

(4) According to the fourth aspect, the image displaying device of the present invention is premised to have, for example, the configuration in (2) and the semiconductor layer is deposited on a first insulation film deposited so as to cover the switching element and connected to the first electrode of the switching element by contact at its one end and to the second electrode formed on the second insulation film that covers the semiconductor layer at the other end through a through-hole formed in the second insulation film.

(5) According to the fifth aspect, the image displaying device of the present invention is premised to have, for example, the configuration in (2) and the switching element is configured as a bottom gate type one and the semiconductor layer is deposited in the same layer as the switching element.

The first electrode is one of the electrodes of the switching element. The electrode is extended onto the surface of the semiconductor layer at its one end side.

The second electrode is connected to the surface of the other end side of the semiconductor layer through a through-hole formed in an insulation film on the surface of the insulation film deposited so as to cover the semiconductor layer.

(6) According to the sixth aspect, the image displaying device of the present invention is premised to have, for example, the configuration in any of (1) to (5) and the semiconductor layer is a non-conductive semiconductor layer.

(7) According to the seventh aspect, the image displaying device of the present invention is premised to have, for example, the configuration in any of (1) to (5) and the semiconductor layer is a conductive semiconductor layer.

(8) According to the eighth aspect, the image displaying device of the present invention is premised to have, for example, the configuration in any of (1) to (5), the semiconductor layer is a non-conductive semiconductor layer and a conductive semiconductor layer is deposited between this non-conductive semiconductor layer and the first electrode.

(9) According to the ninth aspect, the image displaying device of the present invention is premised to have, for example, the configuration in (1) to (5) and the semiconductor layer is an n-type semiconductor layer and a p-type semiconductor layer is deposited between this n-type semiconductor layer and the second electrode.

(10) According to the tenth aspect, the image displaying device of the present invention is premised to have, for example, the configuration in (1) to (5) and the semiconductor layer is a non-conductive semiconductor layer and an n-type semiconductor layer is deposited between this non-conductive semiconductor layer and the first electrode and a p-type semiconductor layer is deposited between this non-conductive semiconductor layer and the second electrode.

(11) According to the eleventh aspect, the image displaying device of the present invention is premised to have, for example, the configuration in (1) to (5) and the semiconductor layer is a non-conductive semiconductor layer and the first electrode is formed with an n-type polycrystalline semiconductor layer.

However, the present invention is not limited only to those configurations described above and modifications are possible without departing the technical concept of the present invention.

The image displaying device having any one of the configurations described above can thus suppress the leakage current from each photo-sensing device, thereby reducing the dark current and further improving the S/N ratio.

### BRIEF DESCRIPTION OF THE DRAWINGS

FIG. 1 is a cross sectional view taken on line I-I of FIG. 3A with respect to a configuration of a major portion of an image displaying device of the present invention in an embodiment;

FIG. 2 is a top view of an image display region of the image displaying device of the present invention;

FIG. 3 is a top view of a photosensing device and a pixel of the image displaying device of the present invention;

FIG. 4 is a graph denoting an effect of the image displaying device of the present invention;

FIG. 5A is a diagram showing one of a series of processes for fabricating the image displaying device of the present invention;

FIG. 5B is another diagram showing one of the series of processes for fabricating the image displaying device of the present invention;

FIG. 5C is still another diagram showing one of the series of processes for fabricating the image displaying device of the present invention;

FIG. 5D is still another diagram showing one of the series of processes for fabricating the image displaying device of the present invention;

FIG. 5E is still another diagram showing one of the series of processes for fabricating the image displaying device of the present invention;

FIG. 6 is a cross sectional view of a major portion of an image displaying device of the present invention in still another embodiment;

FIG. 7 is a top view of the image displaying device of the present invention, corresponding to FIG. 3;

FIG. 8 is a cross sectional view of a major portion of an image displaying device of the present invention in still another embodiment, taken on line VIII-VIII of FIG. 7A;

FIG. 9A is a diagram showing one of a series processes for fabricating the image displaying device of the present invention with respect to the configuration shown in FIG. 8 in an embodiment;

FIG. 9B is another diagram showing one of the series processes, following FIG. 9A;

FIG. 9C is still another diagram showing one of the series processes, following FIG. 9B;

FIG. 9D is still another diagram showing one of the series processes, following FIG. 9C;

FIG. 10 is a cross sectional view of a major portion of an image displaying device of the present invention in still another embodiment;

FIG. 11 is a cross sectional view of a major portion of an image displaying device of the present invention in still another embodiment;

FIG. 12 is a cross sectional view of a major portion of an image displaying device of the present invention in still another embodiment;

FIG. 13 is a cross sectional view of a major portion of an image displaying device of the present invention in still another embodiment;

FIG. 14 is a cross sectional view of a major portion of an image displaying device of the present invention in still another embodiment;

FIG. 15A is a diagram that describes an embodiment of an electronic device to which the present invention can apply;

FIG. 15B is a diagram that describes an embodiment of another electronic device to which the present invention can apply;

FIG. 16A is a diagram that describes an embodiment of still another electronic device to which the present invention can apply; and

FIG. 16B is a diagram that describes an embodiment of still another electronic device to which the present invention can apply.

### DETAILED DESCRIPTION OF THE PREFERRED EMBODIMENTS

Hereunder, there will be described the preferred embodiments of the image displaying device of the present invention with reference to the accompanying drawings.

### First Embodiment

### (Configuration)

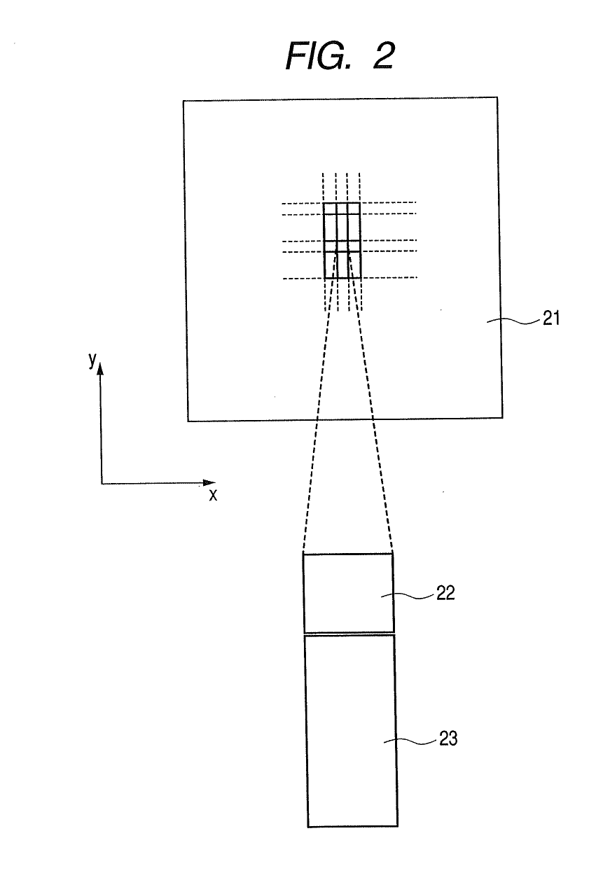

FIG. 2 shows a top view of an image display area 21 of an image displaying device (e.g., liquid crystal display device) of the present invention. In this area 21 are disposed many pixels 23 in a matrix pattern and a photosensing device 22 is disposed between each pair of adjacent pixels 23 positioned, for example, in the y direction in FIG. 2.

In other words, similarly to the pixels 23, the photosensing devices 22 are disposed in a matrix pattern. Each photosensing device 22 is shifted in the y direction from its corresponding pixel 23 and disposed between pixels 23 that are adjacent to each other in the y direction.

In this first embodiment, at a top view, the area of each photosensing device 22 is smaller than that of each pixel 23. This is because each pixel 23 is required to have an aperture ratio preferentially.

Consequently, because each pixel 23 in the image displaying area 21 can be driven independently to visualize an image, the image is projected in the area 21. Then, each photosensing device 22 is driven independently to enable a touch input to be detected.

In case of the configuration of the image displaying device shown in FIG. 2, one pixel 23 corresponds to one photosensing device 22, but one photosensing device 22 can also be disposed to correspond to a plurality of pixels (2 or more) that are adjacent to each another. Touch inputs can be detected if those photosensing devices 22 are disposed in a matrix pattern even when the total number of the photosensing devices 22 is reduced.

Although each photosensing device 22 is shifted from its corresponding pixel 23 in the y direction in FIG. 2, the disposition of those photosensing devices 22 is not limited only to the shifting; it can also be shifted in the x direction.

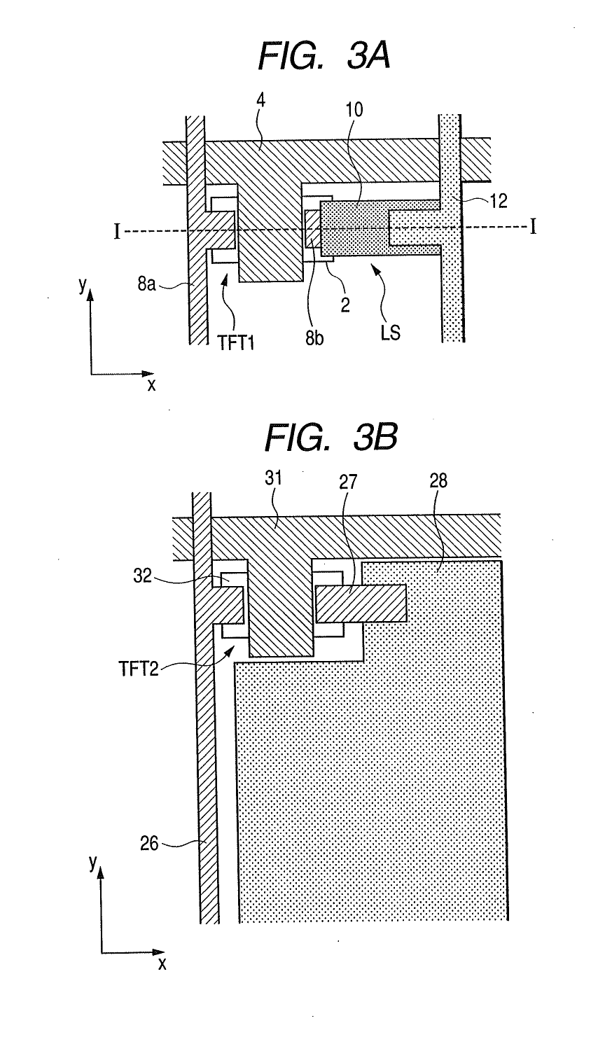

FIG. 3A is a top view of a photosensing device 22 formed on the surface of one (e.g., a substrate 1 disposed far from the observer and closer to the liquid crystal side) of a pair of substrates 1 disposed to face each other with the liquid crystal therebetween.

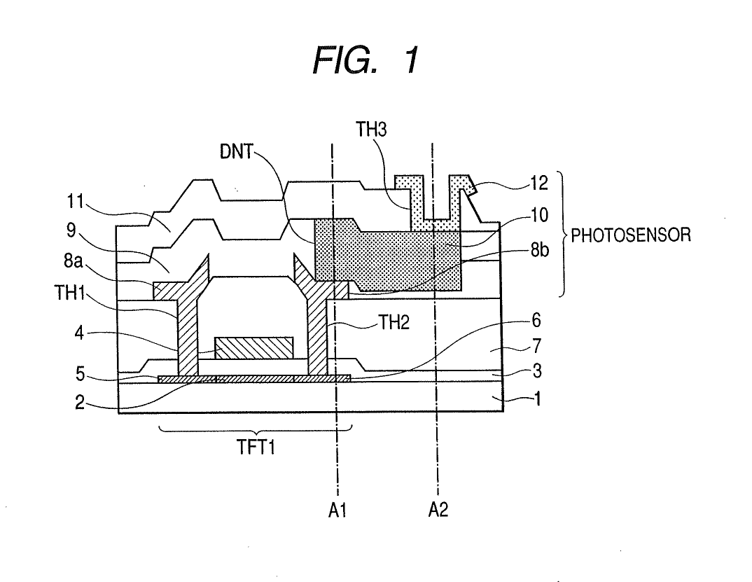

The detailed configuration of this photosensing device 22 will be described later with reference to FIG. 1. Here, a description will be made roughly for the photosensing device 22 with reference to this FIG. 3A.

A thin film transistor TFT1 shown in FIG. 3A is turned on by a signal received through a gate electrode wiring 4 extended in the x direction.

One (source electrode) of the electrodes of the thin film transistor TFT1 is connected to a signal line 8a extended in the y direction in FIG. 3A and the other electrode (drain electrode) 8b thereof is connected to one end of a semiconductor layer 10 of a photo sensor LS. And the other end of the semiconductor layer 10 is connected to a transparent electrode wiring 12 extended in the y direction in FIG. 3A.

In the photosensing device 22 configured in such a way, the semiconductor layer 10 generates a current of which value changes according to whether or not a light is irradiated onto the layer 10. Thus this current is taken out from the signal line 8a at the on-timing of the thin film transistor TFT1 to detect the light irradiation state (on/off).

FIG. 1 is a cross sectional view taken on line I-I of FIG. 3A.

In FIG. 1, there is a substrate and a land-like semiconductor layer 2 is formed in an area on the surface of the substrate 1. In the area, a thin film transistor TFT1 is also formed closer to the liquid crystal side. This semiconductor layer 2 is made, for example, of an amorphous Si film or polycrystalline Si film.

On the surface of the substrate 1 is deposited an insulation film 3 so as to cover the semiconductor layer 2. This insulation film 3 functions as a gate insulation film in the thin film transistor TFT1 formed area.

On the surface of the insulation film 3 is formed a gate electrode 4, over the center of the semiconductor layer 2.

At a top view, the semiconductor layer 2 is formed at a portion protruded from the gate electrode wiring 4; impurities are doped into the protruded portion to form the layer 2. The wiring 4 is used as a mask for the doping. A source region 5 is formed on one side semiconductor layer 2 and a drain region 6 is formed at the other side semiconductor layer 2 with respect to the gate electrode wiring 4.

On the surface of the insulation film 3 is also formed a first interlayer dielectric film 7 that covers the gate electrode wiring 4. The first interlayer dielectric film 7 has through holes TH1 and TH2 that go through the insulation film 3 so as to expose part of the source region 5 and part of the drain region 6 of the semiconductor layer 2 respectively.

On the surface of the first interlayer dielectric film 7 is formed a signal line 8a and a drain electrode 8b. Part of the signal line 8a is connected to the source region 5 of the semiconductor layer 2 through the through-hole TH1 while the drain electrode 8b is connected to the drain region 6 of the semiconductor layer 2 through the through-hole TH2.

On the surface of the first interlayer dielectric film 7 is formed a second interlayer dielectric film 9 so as to cover the signal line 8a and the drain region 8b. In the second interlayer dielectric film 9 is formed a dent DNT so as to be adjacent to, for example, the thin film transistor TFT1 formed region. One end of the dent DNT is formed to expose at least the surface of the drain electrode 8b. In the dent DNT formed in the second interlayer dielectric film 9 is buried the semiconductor layer 10 of the photo sensor LS and the semiconductor layer 10 is connected electrically to the drain electrode 8b.

And on the surface of the second interlayer dielectric film 9 is deposited a protective insulation film 11 so as to cover the semiconductor layer 10. The protective insulation film 11 has a through-hole TH3 formed so as to expose part of the semiconductor layer 10. If the drain electrode 8b is connected to one end of the semiconductor layer 10, the through-hole TH3 is formed so as to expose the other end of the semiconductor layer 10.

On the surface of the second interlayer dielectric film 9 is formed a transparent electrode wiring 12, which is connected to the semiconductor layer 10 through the through-hole TH3.

In case of the photo sensor LS configured in such a way, the contact surface of the semiconductor layer 10 with the drain electrode 8b and the contact surface of the semiconductor layer 10 with the transparent electrode wiring 12 are formed so that their center axes are separated from each other. This means, for example, A1 and A2 in FIG. 1 are separated from each other.

A center axis means an axis passing the center of a contact surface and extended vertically with respect to the contact surface.

Additionally, FIG. 3B is a top view of the pixel 23 formed on the surface of the substrate 1 closer to the liquid crystal side.

As shown in FIG. 3B, there is a scan signal line 31 extended in the x direction. The thin film transistor TFT2 is turned on by a scan signal supplied to this scan signal line 31. The thin film transistor TFT2 is formed so as to include a semiconductor layer 32.

There is also a video signal line 26 extended in the y direction in FIG. 3B. One end of this video signal line 26 is connected to one of the electrodes of the thin film transistor TFT and the other end of the line 26 is connected to the pixel electrode 28 consisting of a transparent conductive film.

Consequently, the video signal supplied to the video signal line 26 also comes to be supplied to the pixel electrode 28 at the on-timing of the thin film transistor TFT2.

The pixel electrode 28 is disposed so as to face its counterpart electrode consisting of a transparent conductive film, which is formed on the liquid crystal side surface of another substrate (not shown) disposed so as to face the substrate 1. An electric field generated according to the difference of the potential from that of the counterpart electrode is applied to the liquid crystal in response to the supplied video signal, then the pixel electrode 28 functions so as to change the light transmission rate.

### (Characteristics)

The photo sensor LS configured as described above thus comes to have a wider gap between the center axes A1 and A2 of the first and second connection surfaces than that of any other conventional configuration in which the center axis A1 of the first connection surface between the semiconductor layer 10 and the drain electrode 8b is aligned to the center axis A2 of the second connection surface between the semiconductor layer 10 and the transparent electrode wiring 12.

Consequently, if the same potential difference is applied between each pair of electrodes of a photo sensor SL when a bias is applied between each pair of those electrodes, the voltage falls less at the Schottky junction between the drain electrode consisting of a metal film and the semiconductor layer 10 in the structure employed in this first embodiment than the conventional structure, so the electric field strength becomes smaller in the depletion layer formed in the Schottky junction at the side closer to the semiconductor layer 10.

In case of the configured as described above, therefore, the photo sensor LS can suppress significantly the leakage current generated by the avalanche effect or tunneling effect.

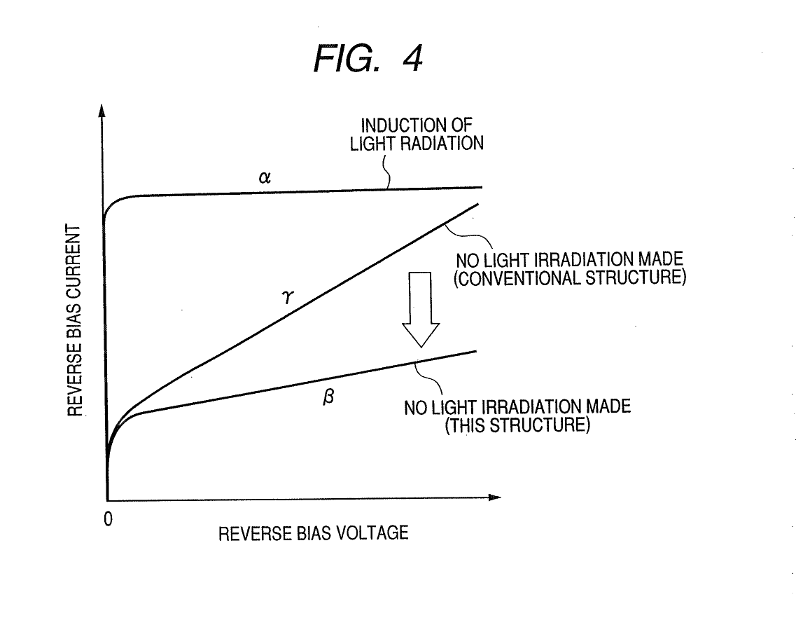

FIG. 4 is a graph denoting the diode characteristics of the photo sensor LS, obtained by the reverse biases when the photo sensor LS is configured as described above. In FIG. 4, the diode characteristics of the conventional photo sensor structure are also shown to compare them with those of the photo sensor LS of the present invention.

At first, the characteristics denoted with α in FIG. 4 are those assured when the light irradiation is on. In this case, there is almost no difference in the reverse bias dependency of the reverse bias current between the structure in this embodiment and the conventional structure. And upon application of a negative voltage, the reverse bias current increases. And when the negative voltage increases, the reverse bias current comes to be almost saturated.

On the other hand, when the light irradiation is off, both a negative voltage and a leakage current are generated, thereby the reverse bias current increases. In this case, the configuration in this first embodiment can reduce the leakage current and suppress the increase of the reverse bias current more effectively (characteristics denoted with β in FIG. 4) than the conventional configuration (characteristics denoted with τ in FIG. 4).

Consequently, the photo sensor in this embodiment that changes its characteristics significantly according to whether or not light irradiation is on can improve the S/N ratio more satisfactorily.

### (Fabricating Method)

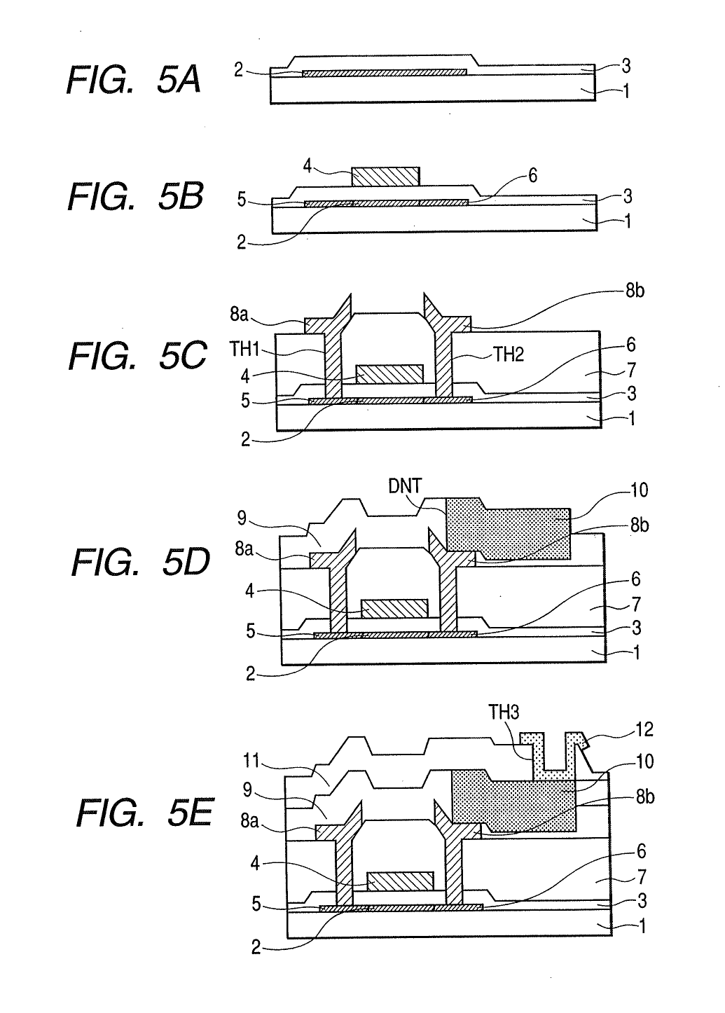

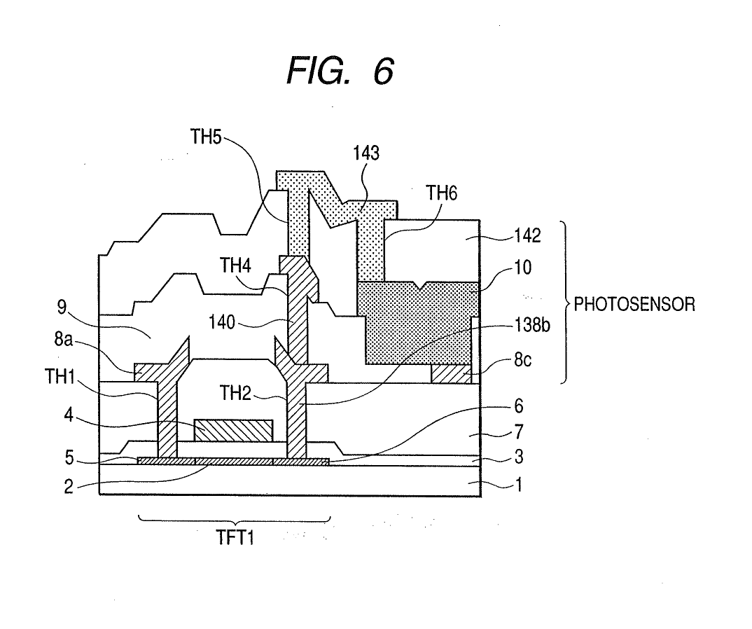

FIG. 5 shows processes for an embodiment of a fabricating method of a portion included in the configuration of the image displaying device shown in FIG. 1. Hereunder, there will be described those processes sequentially.

### Process 1 (FIG. 5A)

At first, a glass substrate 1 is prepared. Then, a semiconductor layer 2 is deposited all over one side surface of the substrate 1. This semiconductor layer 2 can be any of an amorphous Si film containing hydrogen or a polycrystalline Si film.

If an amorphous Si film is to be used as the semiconductor layer 2, the layer should preferably contain hydrogen. This is because if the semiconductor layer 2 is used to form a thin film transistor TFT, the hydrogen can terminate the dangling bond of the Si atoms that might otherwise be caused by the increase of the off-current of the TFT.

If an amorphous Si film is to be used as the semiconductor layer 2, for example, the plasma enhanced CVD (PECVD) can be used to deposit the film. The depositing temperature in this case should preferably be 200° C. to 500° C. The depositing temperature 200° C. or over is required to secure the depositing speed over a certain value so as to improve the fabricating throughput of the thin film transistor TFT. The depositing temperature 500° C. or under is required to suppress desorption of the hydrogen from the amorphous Si film and keep the hydrogen of 2 at % or over in the amorphous Si film, thereby realizing the favorable characteristics of the thin film transistor TFT.

If a polycrystalline Si film is to be used as the semiconductor layer 2, the amorphous Si film deposited as described above is subjected to a laser annealing process to form the layer 2.

The semiconductor layer 2 should be about 10 nm or over in film thickness to avoid lowering of the electron mobility and about 200 nm in film thickness to avoid lowering of the fabricating throughput of the thin film transistor TFT.

After this, the semiconductor layer 2 deposited all over the surface of the substrate 1 is subjected to selective etching that uses the photo-lithograph technique to make the layer a land-shaped one. Each land-shaped semiconductor layer 2 comes to function as a thin film transistor TFT semiconductor layer.

Then, an insulation film 3 consisting of, for example, a silicon oxide film or silicon nitride film is deposited all over the surface of the substrate 1 so as to cover the semiconductor layer 2. This insulation film 3 comes to function as a gate insulation film in the thin film transistor TFT formed region.

The insulation film 3 can be deposited by using the plasma enhanced CVD method or sputtering method. The depositing temperature in this case should preferably be 200° C. to 500° C. The depositing temperature 200° C. and over is required to secure the depositing speed over a certain value so as to improve the fabricating throughput of the thin film transistor TFT. The depositing temperature 500° C. and under is required to suppress desorption of the hydrogen from the amorphous Si film and keep the hydrogen of 2 at % or over in the amorphous Si film, thereby realizing the favorable characteristics of the thin film transistor TFT.

Preferably, the film thickness of the insulation film 3 should be 100 nm. However, the film thickness can be 10 nm and over to cover the semiconductor layer 2 entirely and 300 nm and under so as to assure the operation of the thin film transistor TFT.

### Process 2 (FIG. 5B)

At first, a metal film 4 is deposited all over the surface of the substrate 1 so as to cover the insulation film 3. The metal film 4 can be made of any of No, W, Cr, Ti, Al, Cu, Ni, or the like or an alloy of those elements. The sputtering method can be used for depositing the metal film 4 at a film thickness of, for example, 200 nm.

After this, the metal film 4 is patterned as desired by selective etching that uses the photolithography technique. The metal film 4 left over after the selective etching comes to function as a gate electrode wiring 4 of the thin film transistor TFT.

Then, dopant consisting of Phosphorus (P), Boron (B), or the like is injected into the semiconductor layer 2 by using the gate electrode wiring as a mask. Then, a source region (e.g., left side in the figure) is formed at one side of the gate electrode wiring 4 and a drain region 6 (right side in the figure) at the other side of the wiring 4. And the no-dopant-injected semiconductor layer 2 disposed just under the gate electrode wiring 4 comes to function as a channel region of the thin film transistor TFT.

The concentration of the dopant injection should be 1×10¹⁸ cm⁻³ and over to lower the resistance of the dopant injected region and should be 1×10²¹ cm⁻³ and under to avoid the increase of the resistance that might otherwise occur due to the dopant atom segregation or clustering.

### Process 3 (FIG. 5C)

At first, a first interlayer dielectric film 7 is deposited all over the surface of the substrate 1 so as to cover the gate electrode wiring 4 and the insulation film 3. The first interlayer dielectric film 7 can be almost similar to the insulation film 3 in material selection, depositing method, and depositing temperature. The first interlayer dielectric film can be, for example, 500 nm in film thickness.

After this, through-holes TH1 and TH2 are formed so as to penetrate the first interlayer dielectric film 7 and the insulation film 3 respectively by selective etching that uses the photo-lithography technique. The through-holes TH1 and TH2 expose part of the source region 5 and part of the drain region 6 of the semiconductor layer 2 respectively.

After this, a metal film 8 is deposited all over the surface of the substrate 1 so as to cover the first interlayer dielectric film 7 and the through-holes TH1 and TH2. Consequently, the metal film 8 is connected to part of the source region 5 of the semiconductor layer 2 through the through-hole TH1 and to part of the drain region 6 of the semiconductor layer 2 through the through-hole TH2 respectively.

After this, the metal film 7 is subjected to selective etching that uses the photo-lithography technique to remove all the film except for the portion (source region) connected to the source region 5 of the semiconductor layer 2, the signal line 8a connected to that portion (source region), and the drain electrode 8b connected to the drain region 6 of the semiconductor layer 2.

The metal film 8 can be almost similar to the metal film 4 in material selection and depositing method. The metal film 8 can be, for example, 200 nm in film thickness.

### Process 4 (FIG. 5D)

At first, a second interlayer dielectric film 9 is deposited on the surface of the first interlayer dielectric film so as to cover the signal line 8b and the drain electrode 8b. The interlayer dielectric film 9 can be almost similar to the insulation film 3 or the first interlayer dielectric film 7 in material selection, depositing method, and depositing temperature. The film thickness of the second interlayer dielectric film 9 can be, for example, 500 nm.

After this, the second interlayer dielectric film 9 as large as the photo sensor LS formed region is removed from the surface of the substrate 1 by a predetermined thickness by selective etching that uses the photo-lithography technique, thereby forming a dent DNT. The drain electrode 8b is exposed from part of this dent DNT.

Then, a semiconductor layer 10 is deposited all over the surface of the substrate 1 so as to cover the second interlayer dielectric film 9 and the dent DNT.

The semiconductor layer 10 should preferably be made of amorphous Si to protect the films deposited so far from thermal bad influences. This is because the amorphous Si film can be deposited at low temperatures. And the amorphous Si contains hydrogen that terminates the Si atom dangling bond. This is why the use of hydrogen is favorable.

The semiconductor layer 10 made of this amorphous Si can be almost similar to the semiconductor layer 2 in depositing method, source gas selection, and depositing temperature.

The film thickness of the semiconductor layer 10 should preferably be 10 nm to 1 μm. The film thickness of 10 nm and over is required to assure the S/N ratio of 1 and over for the photo sensor LS and to keep the on-current over a certain value when the light irradiation is on. And the film thickness of 1 μm and under is required so as not to increase the film thickness of the semiconductor layer 10. Otherwise, the surface of the semiconductor layer 10 becomes uneven, thereby exerting bad influences on the display quality.

After this, the semiconductor layer 10 is removed from the surface of the substrate 1 except for the photo sensor formed region by selective etching that uses the photo-lithography technique. As a result, the semiconductor layer 10 is left over and buried just in the dent DNT of the interlayer dielectric film 9.

### Process 5 (FIG. 5E)

At first, a protective insulation film 11 is deposited all over the surface of the substrate 1 so as to cover the first interlayer dielectric film 7 and the semiconductor layer 10. The protective insulation film 11 can be almost similar to the insulation film 3, the first interlayer dielectric film 7, or the second interlayer dielectric film 9 in material selection, depositing method, and depositing temperature. The film thickness of the protective insulation film 11 can be, for example, 500 nm.

After this, a through-hole TH3 is formed through the protective insulation film 11 by selective etching that uses the photo-lithography technique so as to expose part of the semiconductor layer 10. In this case, the through-hole TH3 formed region is separated from the connection region between the drain electrode 8b and the thin film transistor TFT1 of the semiconductor layer 10 as described with reference to FIG. 1.

Then, a transparent conductive film 12 is deposited all over the surface of the substrate 1 so as to cover the protective insulation film 11 and its through-hole. The film 12 is made of, for example, Indium Tin Oxide (ITO), Indium Zinc Oxide (IZO), or ZnO.

The sputtering method can be used to deposit the transparent conductive film 12. The thickness of the film 12 can be, for example, 200 nm.

Then, the transparent conductive film 12 is subjected to selective etching that uses the photo-lithography technique, thereby forming a predetermined pattern thereon. The transparent conductive film 12 left over as a result of the selective etching is connected to the semiconductor layer 10.

### Second Embodiment

### (Configuration)

FIG. 6 is a cross sectional view of a major portion of a liquid crystal display device of the present invention, which corresponds to FIG. 1.

The configuration of the liquid crystal display device of the present invention in this second embodiment differs from that shown in FIG. 1 as follows. The first drain electrode 138b and the second drain electrode 140 of the thin film transistor TFT1 are connected to the semiconductor layer 10 of the photo sensor LS through the transparent electrode wiring 143 consisting of a transparent conductive layer and the electrode wiring 8c connected to the semiconductor layer 10 is formed in the same layer as the drain electrode 138b.

In other words, the electrode wiring 8c is formed in the same layer as the drain electrode 138b on the surface of the first interlayer dielectric film 7.

And the second drain electrode 140 is formed on the second interlayer dielectric film 9 in which the semiconductor layer 10 of the photo sensor is formed and buried therein. The second drain electrode 140 is connected to the drain electrode 138b through the through-hole TH4 formed in the film 9. In this case, the semiconductor layer 10 is connected to the electrode wiring 8c at its bottom.

On the surface of the second interlayer dielectric film 9, through-holes TH5 and TH6 are formed in the protective insulation film 142 deposited so as to cover the second drain electrode 140 and the semiconductor 10. The through-hole TH5 exposes the second drain electrode 140 and the through-hole TH6 exposes part of the semiconductor layer 10.

On the surface of the protective insulation film 142 is formed a transparent electrode wiring 143 and this wiring 143 is connected to the second drain electrode 140 through the through-hole TH5 and to part of the semiconductor layer 10 through the through-hole TH6.

Just like in the first embodiment, in the configuration described above, the contact surface between the semiconductor layer 10 of the photo sensor LS and the transparent electrode wiring 143 and the contact surface between the layer 10 and the electrode wiring 8c are disposed so that their center axes are separated from each other.

### (Fabricating Method)

Hereunder, there will be described an embodiment of the fabricating method for the photo sensor LS with respect to the configuration shown in FIG. 6.

At first, a first interlayer dielectric film 7 is deposited in the configuration shown in FIG. 6. Then, through-holes TH1 and TH2 are formed in the film 7 so as to expose part of the source region 5 and part of the drain region 6 of the semiconductor layer 2 respectively. Those processes are similar to those shown in FIG. 5.

After this, a metal film is deposited on the surface of the first interlayer dielectric film 7 having the through-holes TH1 and TH2 so as to cover those through-holes TH1 and TH2. This metal film can use the same material and the same depositing method as those of the gate electrode wiring 4. The thickness of the metal film can be, for example, 200 nm.

The metal film is then removed by selective etching that uses the photo-lithography technique to remain only the portions connected to the source region 5 through the through-hole TH1 and to the drain region 6 through the through-hole TH2. Those remained portions are then used as a source electrode wiring 8a and a drain electrode wiring 138b respectively.

In the selecting etching that uses the photo-lithography technique, the electrode wiring 8c of the photo sensor LS is formed in the photo sensor LS forming region.

Then, a second interlayer dielectric film 9 is deposited on the surface of the first interlayer dielectric film 7 so as to cover the source electrode wiring 8a, the drain electrode wiring 138b, and the electrode wiring 8c. This second interlayer dielectric film 9 can be almost similar to the second interlayer dielectric film 9 in the first embodiment in material selection, depositing method, depositing temperature, and film thickness.

Then, the photo sensor formed region on the surface of the second interlayer dielectric film 9 is subjected to selective etching that uses the photo-lithography technique to form a dent DNT so as to expose at least the surface of the electrode wiring 8c.

Then, a semiconductor layer is deposited on the surface of the second interlayer dielectric film 9 and the deposited layer is subjected to selective etching that uses the photo-lithography technique to remove the layer except for that left over in the dent DNT as a semiconductor layer 10. The semiconductor layer 10 can be almost similar to that in the first embodiment in material selection, depositing method, depositing temperature, and film thickness.

After this, a through-hole TH4 is formed in the second interlayer dielectric film 9 so as to expose part of the drain electrode 138b therefrom.

Then, a metal film is deposited on the surface of the second interlayer dielectric film 9 having the through-hole TH4 so as to cover the through-hole TH4. This metal film can be the same as the drain electrode 138b in material selection and depositing method. The film thickness can be the same as the height of the semiconductor layer 10 from the surface of the second interlayer dielectric film 9.

The metal film is then subjected to selective etching that uses the photo-lithography technique to remain only the portion connected to the drain electrode 138b through a through-hole. This remained metal film functions as a second drain electrode 140.

Then, a protective insulation film 142 is deposited on the surface of the second interlayer dielectric film 9 so as to cover the second drain electrode 140 and the semiconductor layer 10. The protective insulation film 142 can be almost similar to the protective insulation film 11 in the first embodiment in material selection, depositing method, depositing temperature, and film thickness.

Then, through-holes TH5 and TH6 are formed in the protective insulation film 142 to expose part of the second drain electrode 140 and part of the semiconductor layer 10 respectively.

After this, a transparent electrode film is deposited on the surface of the protective insulation film 142 having the TH5 and TH6 so as to cover those TH5 and TH6. This transparent electrode film 142 can be almost similar to the transparent electrode wiring 12 in the first embodiment in material selection, depositing method, depositing temperature, and film thickness.

Then, a transparent electrode wiring 143 is formed with a minimum portion remained by selective etching that uses the photo-lithography technique. At the remained portion, part of the second drain electrode 140 is connected to part of the semiconductor layer 10 through a through-hole.

The photo sensor LS structured as described in this embodiment is more favorable than that in the first embodiment for the following reasons if a capacitor is connected to a junction with a thin film transistor TFT so as, for example, to hold the charge. It is premised here that the light irradiation on/off is determined according to whether or not the capacitor is charged. In the first embodiment, when the capacitor is not charged, the light irradiation is determined as on and when the capacitor is charged, the light irradiation is determined as off. On the other hand, in case of the structure in this embodiment, when the capacitor is charged, the light irradiation is determined as on and when not, the light irradiation is determined as off. When the photo sensor's determination is changed from on to off, therefore, the capacitor is charged in the first embodiment. In this embodiment, the capacitor is discharged at such a status change. In this case, the capacitor discharging time is shorter than the capacitor charging time. Consequently, the structure in this embodiment is more effective to speed up the determination of the light irradiation on/off than that in the first embodiment.

### Third Embodiment

### (Configuration)

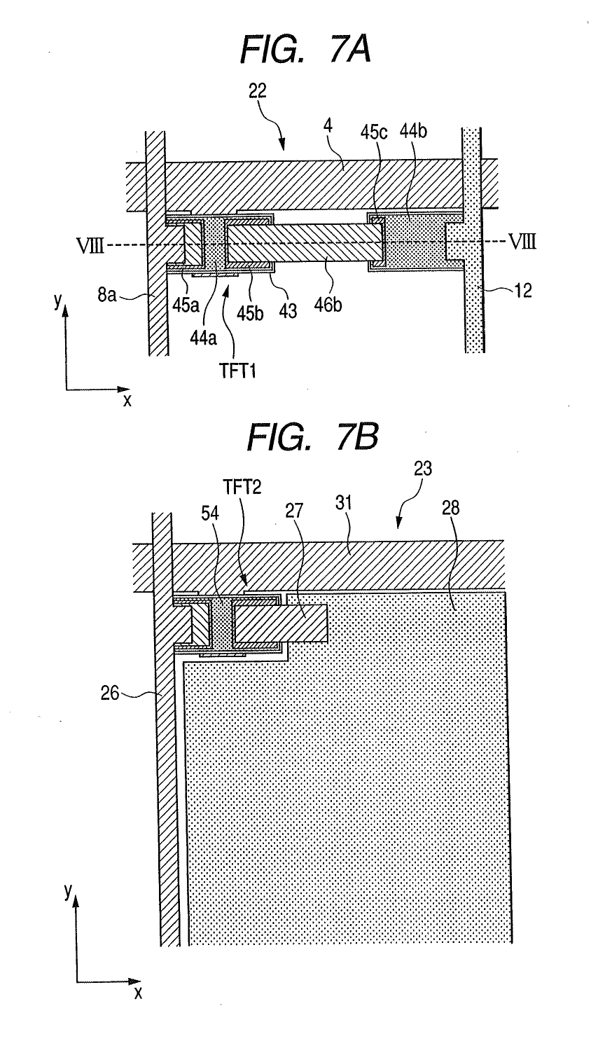

FIG. 7 shows a configuration of an image displaying device of the present invention in a third embodiment. The configuration in this FIG. 7 corresponds to that in FIG. 3.

The configuration in this FIG. 7 differs significantly from that in FIG. 3. The differences are the thin film transistor TFT 1 of the photo sensor 22 and the thin film transistor TFT 2 of the pixel 23. The gate electrode wirings 4 and 31 of the thin film transistor TFT 1 and 2 are disposed under the semiconductor layers 44a and 54 respectively (referred to as so-called bottom gate type ones).

This is why the connection between the thin film transistor TFT 1 and the photo sensor LS comes to be slightly different from that in the configurations described in the above embodiments.

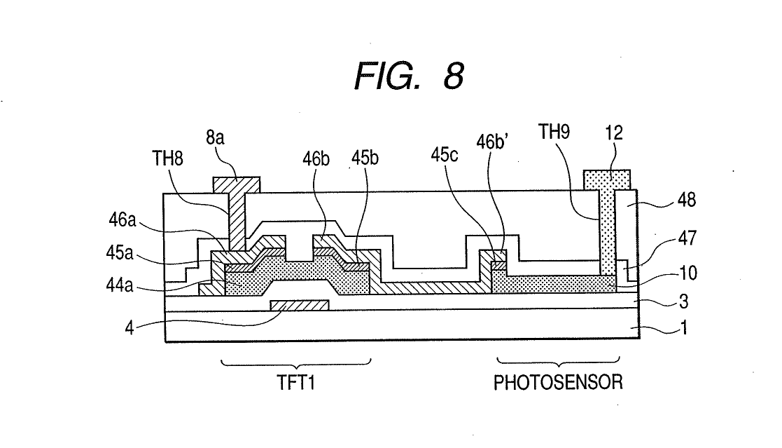

FIG. 8 shows a cross sectional view taken on line VIII-VIII of FIG. 7A.

In FIG. 8, a gate electrode wiring 4 is formed on the surface of the substrate 1 at the side closer to the liquid crystal.

On the surface of the substrate 1 is then formed an insulation film 3 that covers the gate electrode wiring 4. This insulation film 3 functions as a gate insulation film in the region where the thin film transistor TFT1 is formed.

On the surface of the insulation film 3 is formed a land-like semiconductor layer 44a in the region where this thin film transistor TFT1 is formed. In the photo sensor formed region, a land-like semiconductor layer 10 is formed. The semiconductor layer 44a is deposited to stride over the gate electrode wiring 4 and the semiconductor layer 10 is deposited adjacently to the semiconductor layer 44a.

On the surface of the semiconductor layer 44a deposited in the region where the thin film transistor TFT1 is formed are formed a source electrode 46a at one side and a drain electrode 46b at the other side of a region superimposed on the gate electrode wiring 4 provided therebetween.

The drain electrode 46b is formed so as to include an extended portion 46b′ formed in a range from the top surface of the semiconductor layer 44a onto the insulation film 3, then further to the surface of one end of the semiconductor layer 10 of the photo sensor LS. The extended portion 46b′ of the drain electrode 46b is used to form a wiring for connecting the drain electrode 46b to the photo sensor LS.

The source electrodes 46a and the drain electrode 46b on the surface of the semiconductor layer 44a, and furthermore the extended portion 46b′ of the drain electrode 46b on the surface of the semiconductor layer 10 are formed respectively on the high concentration layers 45a, 45b, and 45c in which high concentration n-type impurities are doped. These high concentration layers 45a to 45c function as contact layers.

On the surface of the substrate 1 are stacked an interlayer dielectric film 47 and a protective insulation film 48 in this order so as to cover the source electrode 46a, the drain electrode 46b, and the extended portion 46b′ of the drain electrode 46b.

Furthermore, on the surface of the protective insulation film is formed a signal line 8a. Part of this signal line 8a is connected to part of the source electrode 46a through the through-hole TH8 formed beforehand in the protective insulation film 48. And on the surface of the protective insulation film is formed a transparent electrode wiring 12 and part of this transparent electrode wiring 12 is connected to part of the semiconductor layer 10 of the photo sensor LS through the through-hole TH9 formed beforehand in the protective insulation film 48.

In the configuration described above, just like in the first embodiment, the contact surfaces between the extended portion 46b′ and the drain electrode 46b and between the extended portion 46b′ and the transparent electrode film 12 are disposed so that their center axes are separated from each other.

### (Fabricating Method)

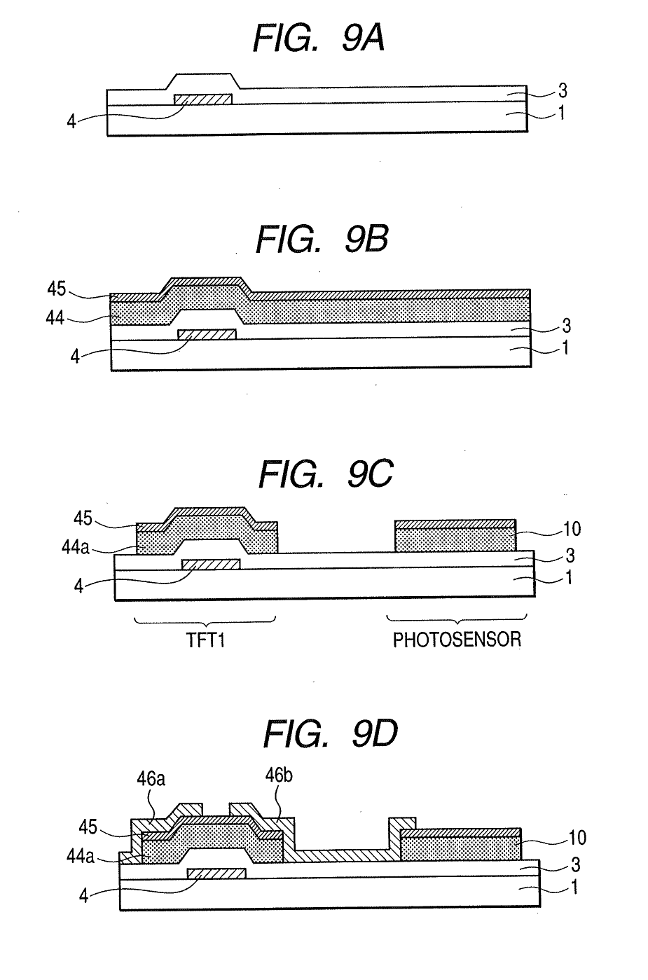

### Process 1 (FIG. 9A)

At first, for example, a glass substrate 1 is prepared. Then, a gate electrode wiring 4 is formed all over the surface of the substrate 1. The gate electrode wiring 4 is almost similar to the gate electrode wiring 4 in the first embodiment in material selection, depositing method, and film thickness.

After that, an insulation film 3 is deposited all over the surface of the substrate 1 so as to cover the gate electrode wiring 4. This insulation film 3 comes to function as a gate insulation film in a region where a thin film transistor TFT1 is formed.

The insulation film 3 is almost similar to the insulation film 3 in the first embodiment in material selection, depositing method, and depositing condition. The film thickness of the insulation film 3 can be, for example, 200 nm.

### Process 2 (FIG. 9B)

At first, a semiconductor layer 44 and a high density conductive impurities-doped semiconductor layer (hereunder, to be referred to as a conductive semiconductor) 45 are stacked sequentially all over the surface of the substrate 1.

The semiconductor layer 44 can be almost similar to the semiconductor layer 2 in the first embodiment in material selection, crystallinity, depositing method, and depositing condition. The film thickness of the semiconductor layer can be, for example, 250 nm.

The conductive semiconductor layer 45 can include phosphorus (P) or Boron (B) as conductive impurities and the film thickness of the layer 45 can be, for example, 50 nm. The doping concentration of the conductive impurities applied to the layer can be almost similar to that in the source region 5 and that in the drain region 6 in the semiconductor layer 2 in the first embodiment. The layer 45 can be almost similar to the semiconductor layer 44 in material selection, crystallinity, depositing method, and depositing condition.

### Process 3 (FIG. 9C)

Then, the layers 44 and 45 are removed by selective etching that uses the photo-lithography technique from all over the surface (top view) of the substrate 1 except for the layers 45 and 44 in the regions where the thin film transistor TFT1 is formed and a photo sensor LS is formed respectively, thereby exposing the insulation film 3 in the remained regions.

### Process 4 (FIG. 9D)

After that, a metal film 46 is deposited all over the surface of the substrate 1 so as to cover the semiconductor layer 44 and the conductive semiconductor layer 45 stacked sequentially on the substrate 1.

The metal film 46 can be almost similar to the gate electrode wiring 4 in material selection and depositing method. The film thickness of the metal film 46 can be, for example, 250 nm.

Then, the metal film 46 is subjected to selective etching that uses the photo-lithography technique to remove all the regions therefrom except for the source electrode 46a of the thin film transistor TFT, the wiring layer connected to the source electrode 46a, and the drain electrode 46b of the thin film transistor TFT and the wiring layer connected to the drain electrode 46b.

In this case, the wiring layer connected to the drain electrode 46b is deposited so as to cover the conductive semiconductor layer 45 at one end of the photo sensor LS at the side closer to the thin film transistor TFT.

After that, although not shown in FIG. 9, the conductive semiconductor layer 45 is subjected to selective etching that uses the photo-lithography technique to remove all the regions therefrom except for the regions of the source electrode wiring 46a, the drain electrode wiring 46, and the extended portion of the drain electrode wiring 46 as shown in FIG. 8. Thus the conductive semiconductor layers 45 (45 to 45c) are remained so as to function as contact layers.

After that, an interlayer dielectric film 47 is deposited all over the surface of the substrate 1. The interlayer dielectric film 47 can be almost similar to the insulation film 3 in the first embodiment in material selection, depositing method, depositing temperature, and film thickness.

Then, a protective insulation film 48 is deposited with, for example, organic composite materials on the surface of the interlayer dielectric film 47. This makes the surface of the protective insulation film 48 smooth. The film thickness of the protective insulation film 48 can be, for example, 500 nm.

After that, a through-hole TH8 is formed in the protective insulation film so as to go through the interlayer dielectric film 47 and expose part of the source electrode 46a of the thin film transistor TFT1. Then, a metal film is deposited on the surface of the protective insulation film 48. The metal film is then subjected to selective etching that uses the photo-lithography technique to form a signal line 8a. This signal line 8a is connected to the source electrode 46a of the thin film transistor TFT1 through the through-hole TH8. This signal line 8a can be almost similar, for example, to the signal line 8 in the first embodiment in material selection, depositing method, depositing temperature, and film thickness.

Furthermore, a through-hole TH9 is formed in the protective insulation film 48 so as to go through the interlayer dielectric film 47, thereby exposing part of the semiconductor layer 10 of the photo sensor LS. Then, a transparent electrode film is deposited on the surface of the protective insulation film 48, then the transparent electrode film is subjected to selective etching that uses the photo-lithography technique to form the transparent electrode wiring 12. This transparent electrode wiring 12 is connected to part of the semiconductor layer 10 through the through-hole TH9. The film thickness of this transparent electrode wiring 12 can be, for example, 200 nm.

In case of the fabricating method for the image displaying device configured in such a way, because the semiconductor layer 44a in the thin film transistor TFT 1 and the semiconductor layer 10 in the photo sensor LS can be formed in the same layer, processes for forming electrodes, etc. can be advanced in parallel, thereby the number of the fabricating processes of the device can be reduced significantly. And the number of interlayer dielectric films to be deposited on the substrate 1 can also be reduced significantly.

Additionally, in the photo sensor LS, a high concentration layer 45c is deposited between the semiconductor layer 10 and the extended portion 46b′ of the drain electrode 46b of the thin film transistor TFT 1 and the extended portion 46b′. Consequently, the resistance of the contact between the semiconductor layer 10 and the drain electrode 46b can be reduced, thereby the power consumption of the device can be reduced.

### Fourth Embodiment

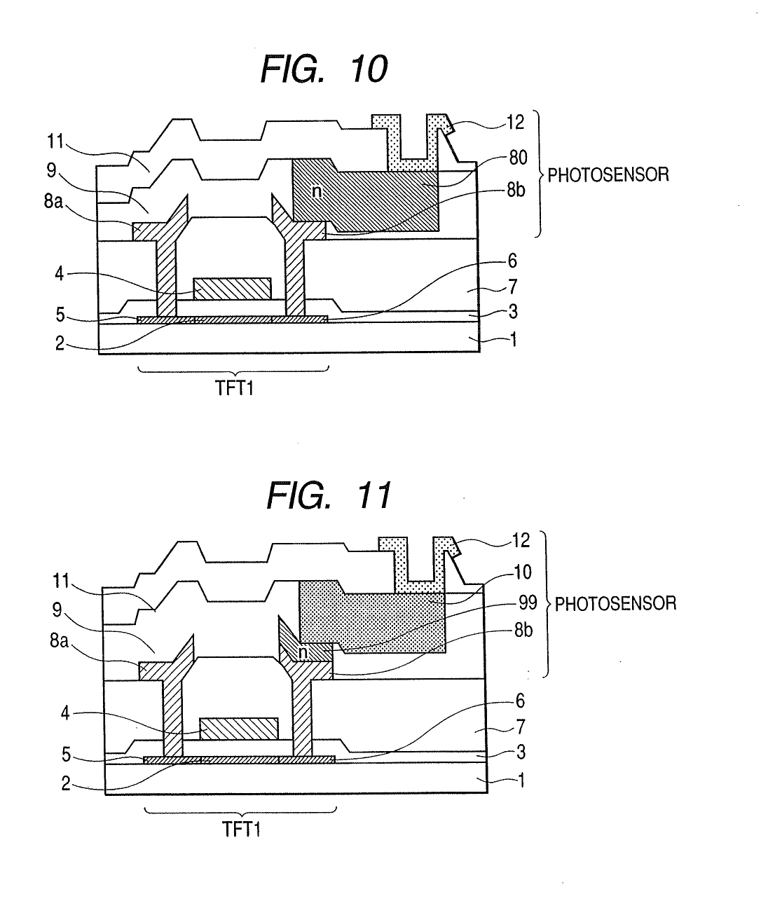

FIG. 10 is a cross sectional view of a major portion of a liquid crystal display device of the present invention in a fourth embodiment. The FIG. 10 corresponds to FIG. 1.

The photo sensor shown in FIG. 10 is configured as a Schottky one. The photoelectric conversion layer of the light sensor LS in FIG. 10 is a conductive semiconductor layer 80; it is not a non-conductive one. This is a significant difference from that shown in FIG. 1.

The semiconductor layer 80 is deposited as, for example, an n-type semiconductor layer. In the first embodiment, upon depositing the semiconductor layer 10, Phosphorous (P) can be injected in the layer 10 as conductive impurities.

The doping concentration of the conductive impurities should preferably be 1×10¹⁷ cm⁻³ and over to assure the n-type characteristics. On the other hand, if the doping concentration is raised excessively, the tunnel current comes to flow easily in the Schottky barrier formed at the junction between the semiconductor layer 80 and the transparent electrode wiring 12. Thus the doping concentration should be set at 1×10²¹ cm⁻³ and under.

The semiconductor layer 80 can be almost similar to the semiconductor layer 10 in the second embodiment in crystallinity, depositing method, and depositing condition. The film thickness of the semiconductor layer 80 can be similar to that of the semiconductor layer 10 in the first embodiment.

Similarly, the semiconductor layer 10 in the second or third embodiment can be replaced with an n-type semiconductor layer.

The photo sensor LS configured as shown in this embodiment is formed as an n-type semiconductor layer 80, which is obtained by doping conductive impurities in the semiconductor layer 80. In the n-type semiconductor layer 80, the height of the Schottky barrier formed in the junction among the drain region 8b, the n-type semiconductor layer 80, and the transparent electrode wiring 12 is higher than that of the photo sensor LS in the first embodiment. Consequently, the photo sensor LS in this embodiment suppresses the increase of the dark current and enables the reverse bias current value to be changed significantly within the wide range of the reverse bias voltage according to whether or not the light irradiation is on. Thus the photo sensor LS can obtain a high S/N ratio satisfactorily.

### Fifth Embodiment

FIG. 11 is a cross sectional view of a major portion of a liquid crystal display device of the present invention in a fifth embodiment. FIG. 11 corresponds to FIG. 1.

The configuration of the device shown in FIG. 11 differs from that shown in FIG. 1 in that a non-conductive semiconductor layer 10 is stacked on the drain electrode 8b with, for example, an n-type semiconductor layer 99 therebetween.

The n-type semiconductor layer 99 is deposited after forming the source electrode 8a and the drain electrode 8b by depositing an n-type semiconductor layer so as to cover the source electrode 8a and the drain electrode 8b on the first interlayer dielectric film 7, then subjecting the layer 99 to selective etching that uses the photo-lithograph technique to remain only the n-type semiconductor layer 99 on the drain electrode 8b. The n-type semiconductor layer 99 can be almost the same as the n-type semiconductor layer 80 in the fourth embodiment in doping concentration, material selection, crystallinity, depositing method, depositing condition, etc. The film thickness of the n-type semiconductor layer 99 can be, for example, 40 nm.

In the second and third embodiments, an n-type semiconductor layer 99 can also be deposited between the semiconductor layer 10 and the electrode wiring 8c or between the conductive semiconductor layer 45c and the semiconductor layer 10, of course.

The photo sensor LS configured as described above enables a wide depletion layer to be formed at the junction between the n-type semiconductor layer 99 and the semiconductor layer 10 at the time of inverse bias application and the carrier generated in the depletion layer at the time of light irradiation to be increased, thereby increasing the reverse bias current. Consequently, the photo sensor LS enables the reverse bias current value to be varied significantly within the wide range of reverse bias voltage according to whether or not the light irradiation is on, so the photo sensor can achieve a high S/N ratio satisfactorily.

### Sixth Embodiment

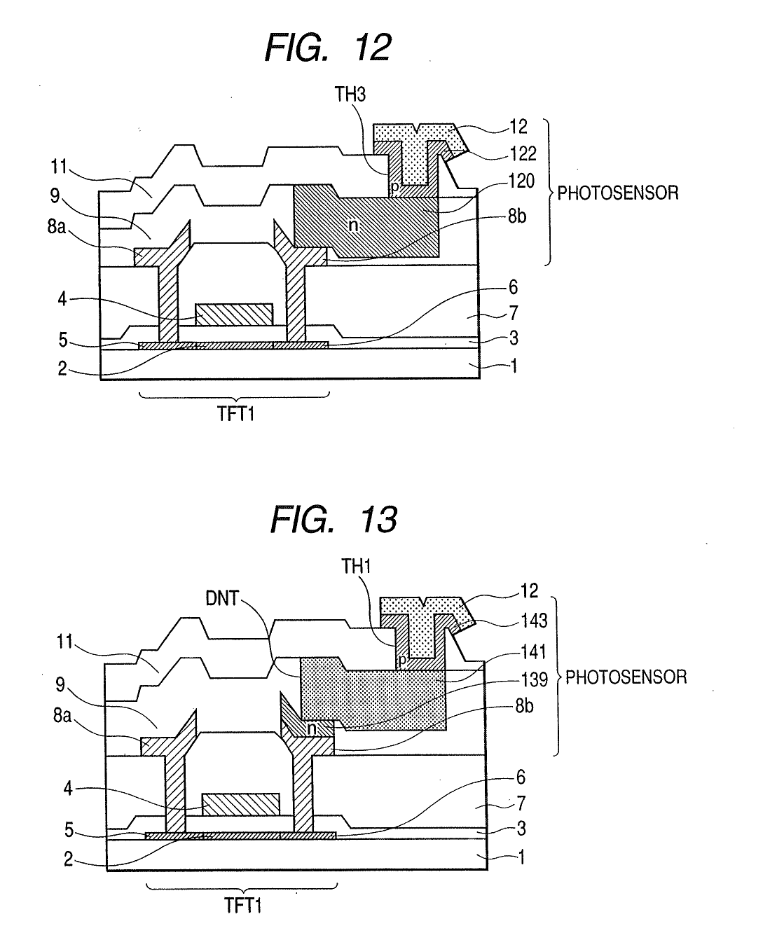

FIG. 12 is a cross sectional view of a major portion of a liquid crystal display device of the present invention in a sixth embodiment. FIG. 12 corresponds to FIG. 1.

The configuration of the device shown in FIG. 12 differs from that shown in FIG. 1 in that the semiconductor layer consists of an n-type semiconductor layer and a p-type semiconductor layer; the layer is a so-called PN junction-type one.

In other words, as shown in FIG. 12, a through-hole TH3 is formed in part of the protective insulation film 11 so as to expose part of the n-type semiconductor layer 120. The protective insulation film 11 is then deposited so as to cover the n-type semiconductor layer 120. After that, a p-type semiconductor layer 122 is deposited so as to cover the inside of and around the through-hole TH3 and so as to form a PN junction with part of the n-type semiconductor layer 120. Then, a transparent electrode wiring 12 is formed on the surface of the p-type semiconductor layer 122.

In the fabricating method, the n-type semiconductor layer 120 can be almost the same as the n-type semiconductor layer 80 in the fourth embodiment in conductive impurities selection, doping concentration, material selection, crystallinity, depositing method, depositing condition, and film thickness.

After that, the protective insulation film 11 is deposited and the through-hole TH3 is formed, the p-type semiconductor layer 122 and the transparent electrode wiring 12 are formed so as to be connected to the n-type semiconductor layer 120 respectively.

Upon depositing the p-type semiconductor layer 122, Boron (B) can be selected as conductive impurities to be doped. The doping concentration should preferably be 1×10¹⁷ cm⁻³ and over to assure the p-type characteristics. On the other hand, the doping concentration should be 1×10²¹ cm⁻³ and under to suppress doping impurities segregation and clustering in the p-type semiconductor layer 122.

The p-type semiconductor layer 122 can be almost the same as the n-type semiconductor layer 99 in the fifth embodiment in material selection, crystallinity, depositing method, depositing condition, and film thickness.

The configuration and fabricating method in the first embodiment can also apply to those in this embodiment with respect to other materials than that of the n-type semiconductor layer 120 and the p-type semiconductor layer 122.

In the second or third embodiment, the semiconductor layer 10 can be replaced with an n-type semiconductor layer and a p-type semiconductor layer can be deposited between the n-type semiconductor layer and the transparent electrode wiring 143 or 12, of course.

In the configuration as described above, the photo sensor employs a PN junction diode, so the reverse bias current can be suppressed more significantly than, for example, the photo sensor that employs the Schottky junction one in any of the first to third embodiments. Consequently, the photo sensor comes to enable the reverse bias current value to be varied significantly within the wide range of the reverse bias voltage according to whether or not the light irradiation is on. Thus the photo sensor can achieve a high S/N ratio satisfactorily.

### Seventh Embodiment

FIG. 13 is a cross sectional view of a major portion of a liquid crystal display device of the present invention in a seventh embodiment. FIG. 13 corresponds to FIG. 1.

Unlike the photo sensor LS in FIG. 1, the semiconductor layer of the photo sensor LS in this FIG. 13 consists of an n-type semiconductor layer 139, a non-conductive semiconductor layer 141, and a p-type semiconductor layer 143 that are stacked on the substrate 1 sequentially. The photo sensor LS is configured as a so-called pin junction type one.

In other words, a non-conductive semiconductor layer 141 is stacked on the drain electrode 8b with an n-type semiconductor layer 139 therebetween. The non-conductive semiconductor layer 141 is buried in the dent DNT formed in the second interlayer dielectric film 9 deposited so as to cover the first interlayer dielectric film 7. And a though-hole TH1 is formed in part of the protective insulation film 11 deposited so as to cover the non-conductive semiconductor layer 141 and to expose part of the non-conductive semiconductor layer 141. Then a p-type semiconductor layer is deposited so as to cover the inside of and around the TH1 and a transparent electrode wiring 12 is formed on the surface of the p-type semiconductor layer 143.

The n-type semiconductor layer 139 can be almost the same as the n-type semiconductor layer 80 in the third embodiment in conductive impurities selection, doping concentration, semiconductor material selection, crystallinity, depositing method, depositing condition, and film thickness.

The non-conductive semiconductor layer 141 can be almost the same as the semiconductor layer 10 in the first embodiment in material selection, crystallinity, depositing method, depositing condition, and film thickness.

The p-type semiconductor layer 143 can be almost the same as the p-type semiconductor layer 122 in the sixth embodiment in conductive impurities selection, doping concentration, semiconductor material selection, crystallinity, depositing method, depositing condition, and film thickness.

The configuration and fabricating method in the first embodiment can also apply to those in this embodiment with respect to other materials than that of the n-type semiconductor layer 139, the non-conductive semiconductor layer 141, and the p-type semiconductor layer 143.

In the second or third embodiment, a non-conductive semiconductor layer and a p-type semiconductor layer can be deposited in the semiconductor layer 10 deposited region and the electrode wiring 8c or conductive semiconductor layer 45c can be connected to the n-type semiconductor layer, and the p-type semiconductor layer can be connected to the transparent electrode wiring 143 or 12 respectively, of course.

In the configuration of the photo sensor described above, a pin junction diode is used, so the depletion layer can be secured wider in the semiconductor layer 141 than the PN junction photo sensor in the sixth embodiment. Therefore, when the light irradiation is turned on, the carrier generation in the depletion layer increases, thereby the reverse bias current also increases. Consequently, the photo sensor enables the reverse bias current value to be varied significantly according to whether or not the light irradiation is on within the wide range of reverse bias voltage, so the photo sensor can achieve a high S/N ratio satisfactorily.

### Eighth Embodiment

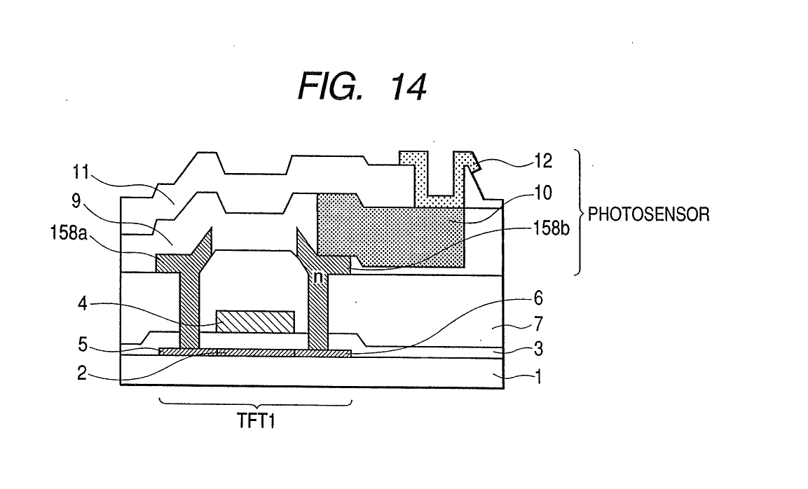

FIG. 14 is a cross sectional view of a major portion of a liquid crystal display device of the present invention in an eighth embodiment. FIG. 14 corresponds to FIG. 1.

The photo sensor LS in this embodiment is composed of Schottky junction diodes. And unlike the configuration shown in FIG. 1, the photo sensor in this embodiment uses an n-type polycrystalline semiconductor layer to form the drain electrode wiring 158b connected to the photo sensor LS.

In this embodiment, the source electrode 158a is also made of an n-type semiconductor layer so as not to make the fabricating processes complicated. In other embodiments, however, only the drain electrode 158b can be made of an n-type semiconductor layer.

The CVD method can be used to deposit the polycrystalline semiconductor layer and Phosphorous (P) can be used as n-type impurities to be doped in the polycrystalline semiconductor layer. The doping concentration of the n-type impurities should preferably be 1×10¹⁸ cm⁻³ and over to lower the resistance and be 1×10²¹ cm⁻³ and under to suppress dopant segregation and clustering that might otherwise be caused by excessive doping.

Furthermore, the film thickness of the n-type polycrystalline semiconductor layer can be, for example, 200 nm, which is the same as that of the source electrode wiring 8a and the drain electrode wiring 8b in the first embodiment.

If the CVD method is used to deposit the polycrystalline semiconductor layer, the depositing temperature becomes about 400 to 600° C. under which hydrogen is easily separated from the amorphous Si layer. To avoid this, therefore, the semiconductor layer 2 of the thin film transistor TFT should preferably be a polycrystalline semiconductor layer.

The configuration and fabricating method in the first embodiment can also apply to those in this embodiment with respect to other materials except for those of the drain electrode 158b.

In the second or third embodiment, the drain electrode wiring 8b can be made of an n-type polycrystalline semiconductor layer, of course.

In the configuration described above, the photo sensor can have a wide depletion layer at a junction between the drain electrode wiring 158b and the semiconductor layer 10, so there is no need to deposit the n-type semiconductor layer between the drain electrode wiring 8b and the semiconductor layer 10, although the layer deposition is required in the fifth embodiment. As a result, the number of fabricating processes can be reduced in this embodiment.

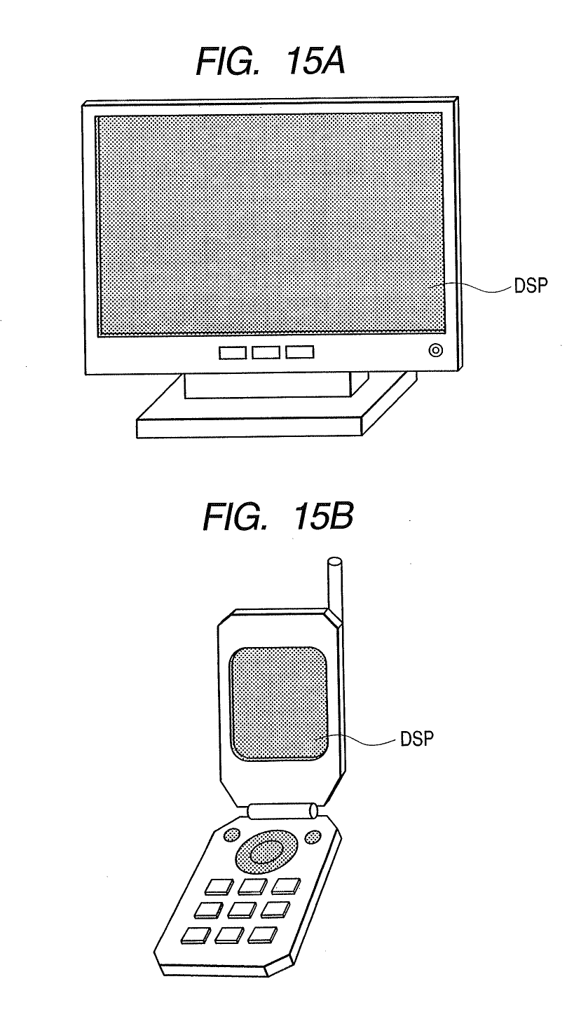

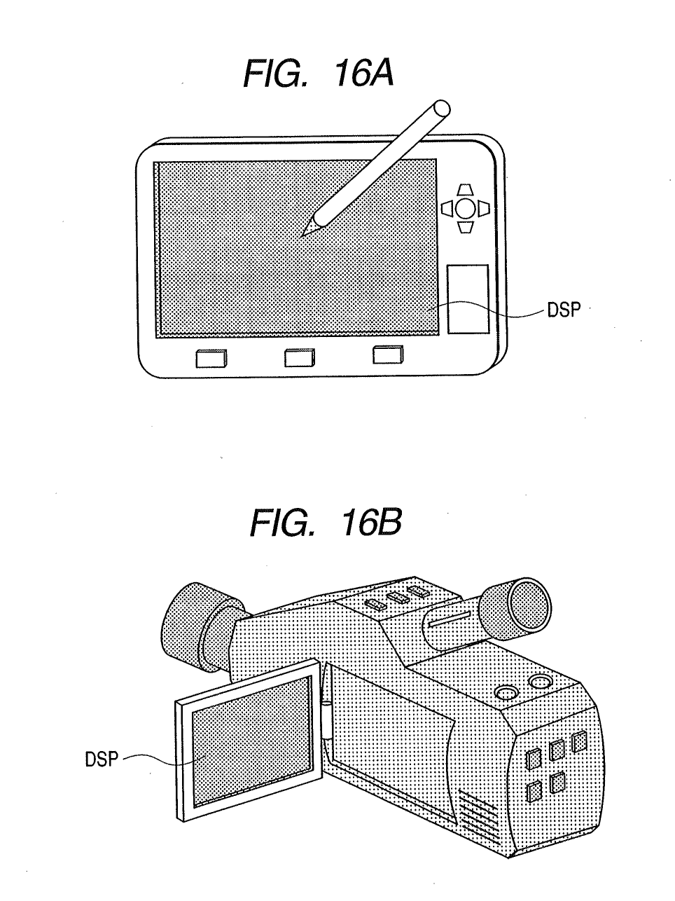

The liquid crystal display device described above can be used as an image displaying device DSP of personal computers as shown in FIG. 15A and as an image displaying device DSP of mobile phones as shown in FIG. 15B. Furthermore, as shown in FIG. 16A, the device can be employed as mobile game machine display devices DSP and as video camera display devices DSP as shown in FIG. 16B. Although not shown here, the device can further be employed as display devices for TV sets, mobile computers, electronic books, digital cameras, as well as head mounting display devices.

In each embodiment described above, a liquid crystal display device provided with photosensing devices has been described. However, the present invention is not limited only to the liquid crystal display device; for example, the present invention can also apply to any other image displaying devices such as organic EL display devices, of course.

Each embodiment described above can be independent or combined with others. This is because the effect in each embodiment can be achieved independently or as a result of combination with others.

What is claimed is:

1. A method of manufacturing an image display device, the image display device including:
a plurality of pixels disposed in a matrix pattern on a substrate, each being driven independently of others; and
a plurality of photosense devices disposed in a matrix pattern, each being driven independently of others, with the pixels and the photosense devices combined into a matrix pattern, each of the photosense devices including a switching element with a first electrode, each of the photosense devices including a semiconductor monolayer that is a photoelectric conversion layer, the switching element being covered with a first insulation film, the first insulation film having a through hole to expose the first electrode,
the method comprising:
forming a second insulation film on the first insulation film and the first electrode;
forming a dent in the second insulation film to expose the first electrode;
embedding the semiconductor monolayer in the dent of the second insulation film, with the semiconductor monolayer electrically connected to the first electrode, making a first interface between the first electrode and the semiconductor monolayer; and
forming a second electrode on the semiconductor monolayer to make a second interface between the second electrode and the semiconductor monolayer, the second interface being positioned so as to completely eliminate overlap with the first interface, when viewed from above the first interface.

2. The method of manufacturing an image display device according to claim 1, wherein each photosense device is configured to take out a current generated in the semiconductor monolayer according to the on-timing of the switching element.

3. The method of manufacturing an image display device according to claim 1, wherein in each photosense devise one end of the semiconductor monolayer is connected to the first electrode, which also functions as one of the two electrodes of the switching element, and the other end of the semiconductor monolayer is connected to the second electrode.

4. The method of manufacturing an image display device according to claim 1, further comprising:
forming a third insulation film to cover the semiconductor monolayer; and
forming a through-hole in the third insulation film to expose the semiconductor monolayer,
wherein the second electrode is formed on the third insulation film and in the through-hole of the third insulation film.
